(19) United States
(12) Patent Application Publication
(10) Pub. No.: US 2007/0202669 A1
(43) Pub. Date: Aug. 30, 2007

(54) Epitaxial growth method and semiconductor device fabrication method

(75) Inventors: Masahiro Fukuda, Kawasaki (JP); Yosuke Shimamune, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/507,524

(22) Filed: Aug. 22, 2006

(30) Foreign Application Priority Data
Feb. 27, 2006 (JP) 2006-051106

(51) Int. Cl. H01L 21/20; H01L 21/36

(52) U.S. Cl. 438/507; 257/E21.463

(57) ABSTRACT

An epitaxial growth method and a semiconductor device fabrication method that improve selectivity in epitaxial growth. A gate electrode is formed over an Si substrate with a gate insulating film there between (step S1). An insulating layer is formed on the sides of the gate electrode (step S2). Portions in the Si substrate where source/drain electrodes are to be formed are etched to form recess regions (step S3). After that, HCl-H₂ mixed gas for suppressing semiconductor growth on the insulating layer is supplied onto the Si substrate and the insulating layer (step S4) and SiH₄-GeH₄ mixed gas is supplied (step S5). By doing so, the growth of SiGe can be suppressed on the insulating layer and an SiGe layer can be made to selectively epitaxial-grow in the recess regions as the source/drain electrodes.

### CROSS-REFERENCE TO RELATED APPLICATIONS

This application is based upon and claims the benefits of priority from the prior Japanese Patent Application No. 2006-051106, the entire contents of which are incorporated herein by reference.

### BACKGROUND OF THE INVENTION

(1) Field of the Invention

This invention relates to an epitaxial growth method and a semiconductor device fabrication method and, more particularly, to an epitaxial growth method for making a semiconductor selectively epitaxial-grow and a semiconductor device fabrication method using such an epitaxial growth method.

(2) Description of the Related Art

Attention has recently been riveted on an elevated or recessed source/drain MOSFET in which a silicon (Si) film or a silicon germanium (SiGe) film is formed in source/drain regions of a MOSFET. It is expected that these MOSFETs will be utilized as techniques for improving the performance of transistors beyond the 90 nm node.

A structure in which an SiGe layer, for example, is made to epitaxial-grow on an Si substrate is adopted in source/drain regions especially in a recessed source/drain MOSFET. If the SiGe layer is made to epitaxial-grow in the source/drain regions, a channel region is compressed from the direction of a source/drain because the lattice constant of SiGe is greater than the lattice constant of Si. This improves hole mobility in the channel region. Therefore, with this type of MOSFET, current driving capability can be enhanced significantly.

The method of making the SiGe layer selectively epitaxial-grow only on the Si substrate is adopted to make the SiGe layer epitaxial-grow in the source/drain regions of the recessed source/drain MOSFET. By making the SiGe layer selectively epitaxial-grow only in the recessed source/drain region, source/drain electrodes are electrically separated from a gate electrode by an insulating layer which is a side wall. With such an element, it is important to suppress an OFF-state leakage current which flows between a source/drain electrode and a gate electrode.

In actual selective epitaxial growth, however, there are cases where an SiGe layer also grows on a side wall because of low selectivity between an Si substrate and an insulating layer (deterioration in selectivity). FIG. 7 is a sectional view showing an important part of a recessed source/drain MOSFET in which a deterioration in selectivity has occurred. As can be seen from FIG. 7, an SiGe layer 230 is formed not only on source/drain electrodes 210 on a substrate 200 but also on side walls 220 which are insulating layers. In this case, the source/drain electrodes 210 are electrically connected to a gate electrode 240 and an excessive OFF-state leakage current flows between the source/drain electrodes 210 and the gate electrode 240. As a result, a function as a MOSFET is lost. Factors in a deterioration in selectivity have not fully been clarified because it is caused by a complicated surface reaction. However, the following, for example, may be a factor in a deterioration in selectivity.

Insulating layers formed in an LSI manufacturing process are mainly an Si oxide film and an Si nitride film. These films are formed by various methods such as thermal chemical vapor deposition (CVD) and plasma CVD. The state of the surface of an insulating layer formed depends on a growth method. All the surface of an insulating layer is not in a state of saturated bonding. For example, dangling bonds or the like are exposed in some portions of the surface of an insulating layer. If semiconductor material gas adsorbs to a dangling bond or the like, a semiconductor nucleus begins to grow on the insulating layer after the elapse of a certain period of time (latent period). This nucleus grows to a film. As a result, a semiconductor film is formed on the insulating layer.

To establish a selective growth process, it is preferable that the latent period on the insulating layer should be lengthened substantially. However, the latent period depends on the state of the surface of the insulating layer, a growth condition, or the like. Accordingly, really an ample latent period is not secured, depending on the state of the surface of the insulating layer, a growth condition, or the like.

As stated above, in an actual selective epitaxial growth process it is difficult to make a semiconductor film epitaxial-grow only on the surface of a specific semiconductor.

To solve this problem, an attempt to utilize an etching technique is made. This method comprises the steps of adding hydrogen chloride (HCl) gas for etching to semiconductor material gas and making SiGe selectively epitaxial-grow only on the surface of a semiconductor substrate while etching SiGe which grows on an insulating layer (see, for example, Japanese Patent Laid-Open Publication No. 2004-363199 and T. I. Kamins, G. A. D. Briggs. and R. Stanley Williams, “Influence of HCl on the chemical vapor deposition and etching of Ge islands on Si(001)” APPLIED PHYSICS LETTERS, vol. 73, no. 13, pp. 1862-1864 (1998)).

With the above method using an etching technique, however, the temperature of the substrate must be higher than or equal to 600° C. to increase the rate at which SiGe that grows on the insulating layer is etched by, for example, HCl. If the temperature of the substrate is higher than or equal to 600° C., the influence of the thermal diffusion of impurities contained in the element in extremely small quantities becomes powerful. In addition, the SiGe layer and the insulating layer are, for example, eroded by HCl.

On the other hand, if the temperature of the substrate is lower than or equal to 600° C., the rate at which SiGe is etched by HCl is slow. Accordingly, even if semiconductor material gas is mixed with HCl gas as additive gas at the time of the selective epitaxial growth of SiGe, the rate at which SiGe is etched is slower than the rate at which SiGe grows. As a result, SiGe also grows on the insulating layer. This means that a manufacturing process condition suitable for actual mass production cannot be obtained.

### SUMMARY OF THE INVENTION

The present invention was made under the background circumstances described above. An object of the present invention is to provide an epitaxial growth method which can make a semiconductor epitaxial-grow very selectively.

Another object of the present invention is to provide a semiconductor device fabrication method which suppresses a leakage current and which can be used for real mass production.

In order to achieve the above first object, there is provided an epitaxial growth method for making a semiconductor selectively epitaxial-grow, comprising the steps of supplying a material for suppressing semiconductor growth on an insulating layer onto a surface on which the insulating layer and a first semiconductor layer are exposed; and supplying a material for forming a second semiconductor layer onto the surface onto which the material for suppressing the semiconductor growth is supplied.

In addition, in order to achieve the above second object, there is provided a semiconductor device fabrication method comprising the steps of forming a gate electrode over a semiconductor substrate with a gate insulating film there between, forming an insulating layer on sides of the gate electrode, partially recessing the semiconductor substrate on both sides of the insulating layer, supplying a material for suppressing semiconductor growth on the insulating layer onto a surface on which the insulating layer and the semiconductor substrate recessed are exposed, and forming source/drain electrodes by supplying a material for a semiconductor layer onto the surface onto which the material for suppressing the semiconductor growth is supplied and by making the semiconductor layer epitaxial-grow on the semiconductor substrate recessed.

The above and other objects, features and advantages of the present invention will become apparent from the following description-when taken in conjunction with the accompanying drawings which illustrate preferred embodiments of the present invention by way of example.

### BRIEF DESCRIPTION OF THE DRAWINGS

FIG. 1 is an example of a flow chart of fabricating a semiconductor device by using selective epitaxial growth.

FIG. 2 is a sectional view showing an important part of the step of recessing a semiconductor substrate.

FIG. 3 is a sectional view showing an important part of the step of supplying HCl-H₂ mixed gas.

FIG. 4 is a sectional view showing an important part of the step of forming source/drain electrodes.

FIG. 5 is a SEM image of the surface of a CVD-Si nitride film of sample A.

FIG. 6 is a SEM image of the surface of a CVD-Si nitride film of sample B.

FIG. 7 is a sectional view showing an important part of a recessed source/drain MOSFET in which a deterioration in selectivity has occurred.

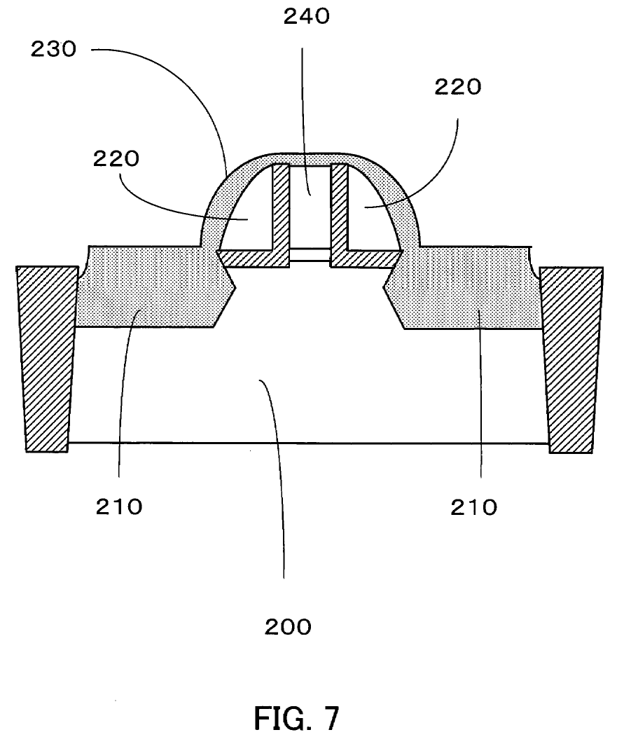

### DESCRIPTION OF THE PREFERRED EMBODIMENTS

Embodiments of the present invention will now be described in detail with reference to the drawings.

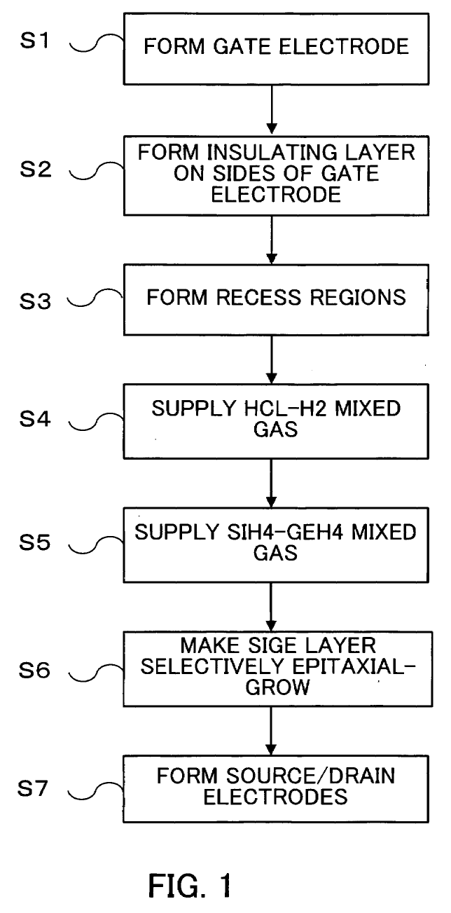

FIG. 1 is an example of a flow chart of fabricating a semiconductor device by using selective epitaxial growth. First, an Si substrate is used as a first semiconductor layer and a gate electrode is formed on the Si substrate (step S1). An insulating layer which serves as side walls is then formed on the sides of the gate electrode (step S2). After that, portions in the Si substrate where source/drain electrodes are to be formed are etched to form recess regions (step S3). A material, such as HCl-hydrogen (H₂) mixed gas, for suppressing epitaxial growth on the insulating layer is then supplied onto the recess regions of the Si substrate and the insulating layer which serves as side walls (step S4). After that, gas, such as monosilane (SiH₄)-monogermane (GeH₄) mixed gas, used for forming a second semiconductor layer is supplied (step S5). By doing so, an SiGe layer, being the second semiconductor layer, is made to selectively epitaxial-grow in the recess regions (step S6), and the source/drain electrodes of the SiGe layer with predetermined thickness are formed (step S7).

As stated above, by supplying a material, such as HCl, for suppressing epitaxial growth on the insulating layer onto the Si substrate in which the recess regions have been formed and the insulating layer which serves as side walls, dangling bonds on the surface of the insulating layer is eliminated by Cl radicals. As a result, the growth of SiGe is suppressed on the insulating layer and the SiGe layer selectively epitaxial-grows on the Si substrate.

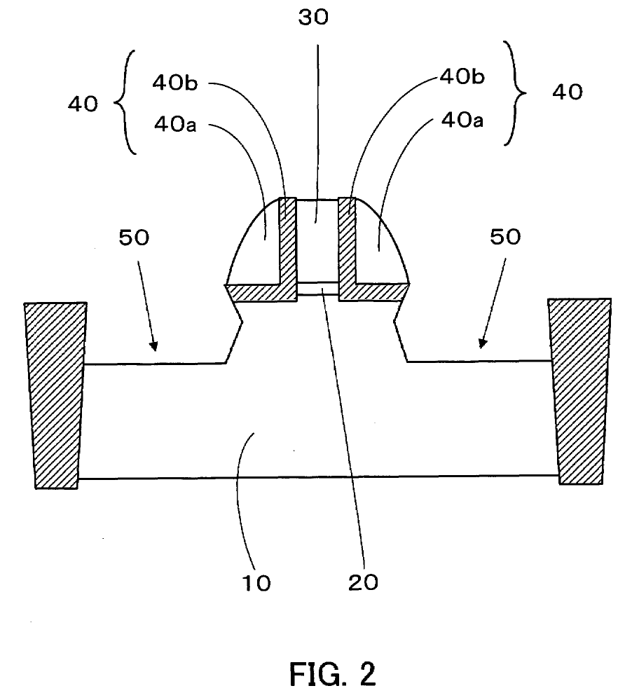

Each fabrication step will now be described concretely. Each of FIGS. 2 through 4 is a sectional view showing an important part of the step of making a SiGe layer selectively epitaxial-grow in recess regions of a semiconductor substrate in the process for fabricating a recessed source/drain MOSFET.

FIG. 2 is a sectional view showing an important part of the step of recessing the semiconductor substrate. An Si substrate 10 is used as a semiconductor substrate, being a first semiconductor. A gate electrode 30 is formed over the Si substrate 10 with a gate insulating film 20 there between. An insulating layer 40 which serves as side walls and which includes an Si nitride film 40a and an Si oxide film 40b deposited by, for example, a CVD method is formed on both sides of the gate electrode 30. Recess regions 50 are formed in the Si substrate 10 by etching. At this stage the surface of the Si substrate 10 in the recess regions 50 and the surface of the insulating layer 40 are exposed.

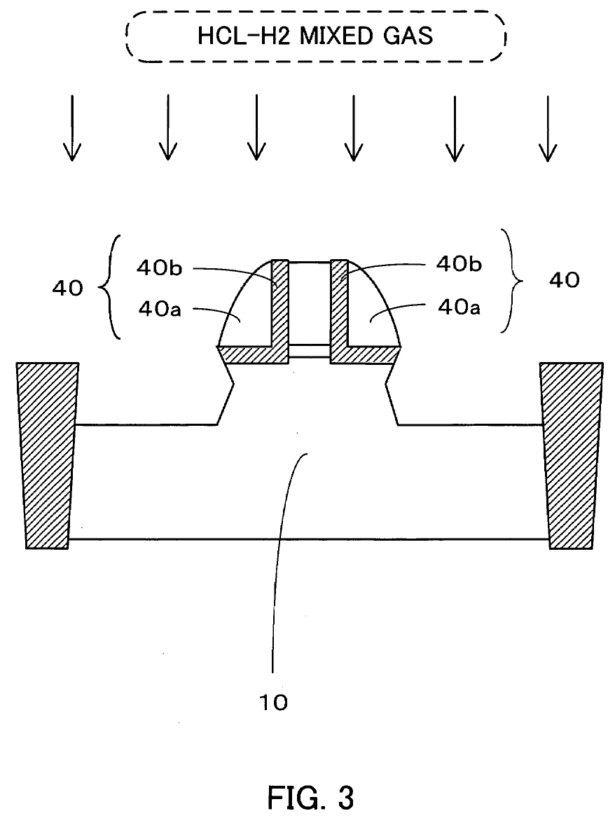

FIG. 3 is a sectional view showing an important part of the step of supplying HCl-H₂ mixed gas. HCl-H₂ mixed gas is supplied onto the surface of the Si substrate 10 recessed by etching and the surface of the insulating layer 40 to expose the surface of the Si substrate 10 and the surface of the insulating layer 40 to HCl. In this case, H₂ is carrier gas for HCl.

The temperature of the Si substrate 10 onto which HCl-H₂ mixed gas is supplied should be set to 450 to 600° C. If the temperature of the Si substrate 10 is higher than 600° C., the influence of the thermal diffusion of impurities contained in the element in extremely small quantities becomes powerful. In addition, the Si substrate 10, the Si nitride film 40a, and the Si oxide film 40b are etched by HCl. On the other hand, if the temperature of the Si substrate 10 is lower than 450° C., HCl does not decompose well on the surface of the insulating layer 40. Therefore, it is difficult to eliminate dangling bonds on the surface of the insulating layer 40 by Cl radicals. HCl-H₂ mixed gas is supplied for 1 to 10 minutes.

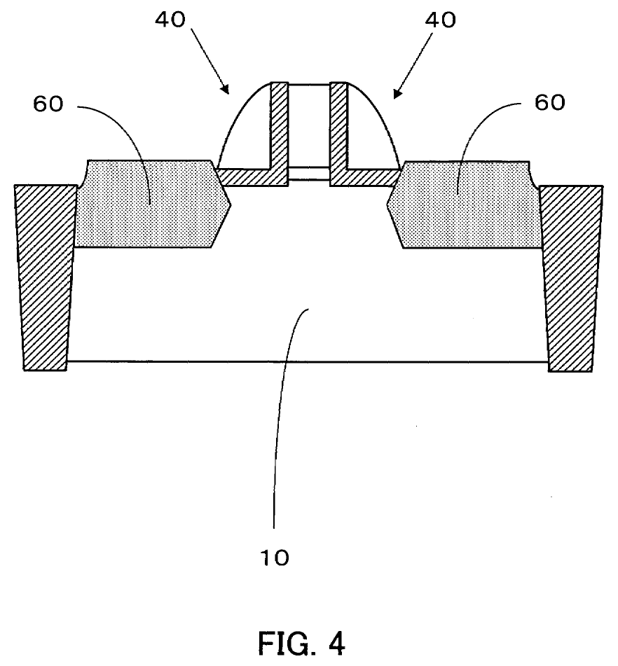

FIG. 4 is a sectional view showing an important part of the step of forming source/drain electrodes. After the surface of the Si substrate 10 recessed and the surface of the insulating layer 40 are exposed to HCl-H₂ mixed gas in the above way, gas, such as SiH₄-GeH₄ mixed gas, used for forming a second semiconductor layer is supplied onto the surface of the Si substrate 10 and the surface of the insulating layer 40.

When SiH₄-GeH₄ reaches the surface of the Si substrate 10, SiH₄-GeH₄ decomposes and an SiGe layer 60 self-restrainingly epitaxial-grows on the surface of the Si substrate 10.

On the other hand, electrons are not supplied to the surface of the insulating layer 40. Therefore, even when SiH₄-GeH₄ reaches the surface of the insulating layer 40, it is difficult for SiH₄-GeH₄ to decompose. HCl is supplied in the preceding step, so dangling bonds which are exposed on the surface of the insulating layer 40 are eliminated by Cl radicals. Accordingly, it is easy for SiH₄-GeH₄ which reaches the surface of the insulating layer 40 to go away from the surface of the insulating layer 40 in its original condition. That is to say, SiGe grows on the Si substrate 10 and it is difficult for SiGe to grow on the insulating layer 40. As a result, there is a time difference between the beginning of the growth of SiGe on the Si substrate 10 and the insulating layer 40 and the epitaxial growth of SiGe is suppressed on the insulating layer 40.

The supply of SiH₄-GeH₄ mixed gas should be terminated before SiGe grows on the insulating layer 40. By doing so, the SiGe layer 60 is formed on the surface of the Si substrate 10.

By following the above steps, the SiGe layer 60, being the second semiconductor layer, can be made to selectively epitaxial-grow on the surface of the Si substrate 10, being the first semiconductor.

At this time the temperature of the Si substrate 10 should be set to 450 to 600° C. If the temperature of the Si substrate 10 is higher than 600° C., the influence of the thermal diffusion of impurities contained in the element in extremely small quantities becomes powerful. In addition, the Si substrate 10 and the insulating layer 40 are etched by HCl which remains on the surfaces of the Si substrate 10 and the insulating layer 40. On the other hand, if the temperature of the Si substrate 10 is lower than 450° C., it is difficult for SiH₄ to decompose on the surface of the Si substrate 10. Therefore, SiGe does not epitaxial-grow on the Si substrate 10.

The effect of suppressing the growth of SiGe by exposing an insulating layer to HCl-H₂ mixed gas will now be described. Each sample used for checking this effect is obtained by making a CVD-Si nitride film grow on the surface of a wafer. The difference between an effect obtained in the case where the surface of an Si nitride film is exposed to HCl-H₂ mixed gas and an effect obtained in the case where the surface of an Si nitride film is not exposed to HCl-H₂ mixed gas will be described. In this case, the total pressure of HCl-H₂ mixed gas is 10 Pa.

Two samples A and B were prepared. Sample A was prepared in the following way. The surface of an Si nitride film is not exposed to HCl-H₂ mixed gas before the supply of SiH₄-GeH₄ mixed gas. SiH₄-GeH₄ mixed gas is supplied onto the Si nitride film. Sample B was prepared in the following way. The surface of an Si nitride film is exposed to HCl-H₂ mixed gas before the supply of SiH₄-GeH₄ mixed gas. SiH₄-GeH₄ mixed gas is then supplied directly onto the Si nitride film. With samples A and B, SiH₄-GeH₄ mixed gas is supplied for 60 minutes.

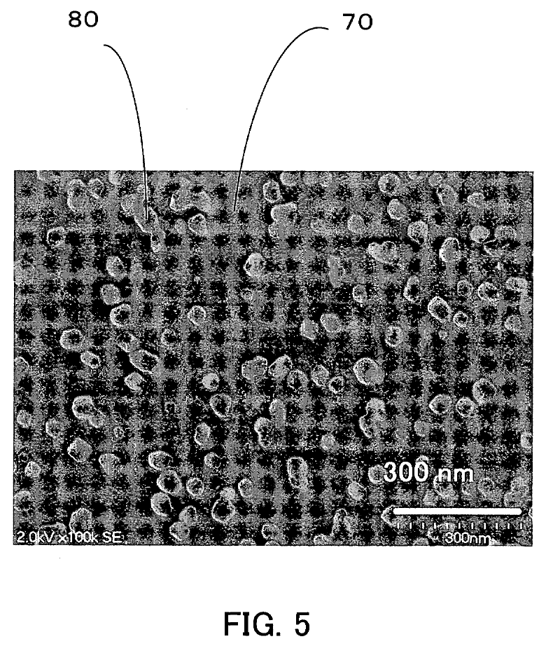

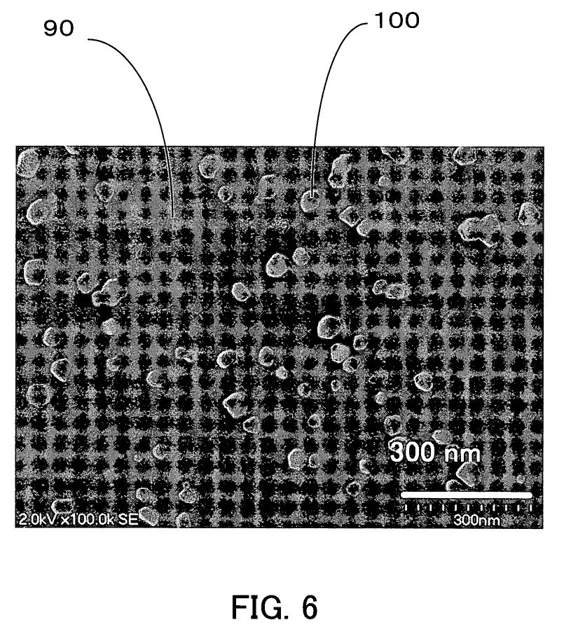

FIG. 5 is a SEM image of the surface of the CVD-Si nitride film of sample A. As can be seen from FIG. 5, SiGe particles 80 have grown on an Si nitride film 70. The SiGe particles 80 each having a diameter smaller than or equal to 60 nm have discretely grown. FIG. 6 is a SEM image of the surface of the CVD-Si nitride film of sample B. In FIG. 6, SiGe particles 100 each having a diameter smaller than or equal to 60 nm have discretely grown on an Si nitride film 90. The number of the SiGe particles 100 is small compared with sample A shown in FIG. 5.

A total reflection X-ray fluorescence analysis of sample B shows that just after the surface of the Si nitride film is exposed to HCl-H₂ mixed gas, Cl remains on the surface of the Si nitride film. That is to say, it is conceivable that Cl radicals which adsorb to the surface of the Si nitride film will have the effect of suppressing the growth of SiGe on the insulating layer.

In the above example, the total pressure of HCl-H₂ mixed gas is 10 Pa when sample B is prepared. However, the effect of suppressing the growth of SiGe on the insulating layer can be obtained if the partial pressure of HCl is 1 to 700 Pa, the partial pressure of H₂ is higher than or equal to 1 Pa and lower than 10,000 Pa, and the total pressure of HCl-H₂ mixed gas is 10 to 10,000 Pa.

It turned out that even if the surface of the Si substrate is exposed to HCl gas, damage is not caused by etching at temperatures between 450 and 600° C.

After the surface of the Si substrate was exposed to HCl gas, the rate at which SiGe epitaxial-grows on the Si substrate did not decrease at temperatures between 450 and 600° C. To be concrete, a film was formed in as little as one or two minutes and a uniform film with a thickness of 30 to 40 nm was formed after 60 minutes.

It turns out from these results that by supplying HCl onto the Si substrate the temperature of which is between 450 and 600° C., the epitaxial growth of the semiconductor is not suppressed on the Si substrate and is suppressed on the insulating layer.

In the above example, HCl-H₂ mixed gas is used as a material for suppressing epitaxial growth on the insulating layer. However, hydrogen bromide (HBr), being another halogenated hydrogen, may be used in place of HCl. Furthermore, chlorine (Cl₂) or bromine (Br₂) may be used in place of halogenated hydrogen. In addition, such a gas may be mixed with H₂ as carrier gas.

SiGe or germanium (Ge), which is also a semiconductor, may be used as the first semiconductor substrate in place of the Si substrate. Si or Ge may be used as the second semiconductor layer, of which the source/drain electrodes are formed, in place of SiGe.

Si₂H₆ (disilane) and Ge₂H₆ (digermane) may be used as a material for the second semiconductor layer in place of SiH₄ and GeH₄. These gases may be mixed with H₂ as carrier gas. To suppress a deterioration in selectivity more strongly, a material for the second semiconductor layer may be mixed with HCl.

In addition, a material for the second semiconductor layer may be mixed with, for example, B₂H₆ (diborane) as dopant gas. Even at a high boron (B) concentration (about 1E20 cm⁻²), the electroactivity of boron in a film is about 100% and low resistivity can be realized. In this case, ion implantation and heat treatment performed after that for activation are unnecessary.

As can be seen from the foregoing, selectivity in a selective epitaxial growth method used at a substrate temperature between 450 and 600° C. is improved and a manufacturing process condition suitable for actual mass production is secured.

In the present invention, a material for suppressing semiconductor growth on the insulating layer is supplied onto the insulating layer and the first semiconductor layer the surfaces of which are exposed. In addition, a material for forming the second semiconductor layer is supplied onto the insulating layer and the first semiconductor layer. By doing so, the second semiconductor layer is made to selectively epitaxial-grow on the surface of the first semiconductor layer.

Accordingly, an epitaxial growth method by which the formation of the second semiconductor layer is suppressed on the insulating layer and by which the second semiconductor layer selectively grows on the surface of the first semiconductor layer can be provided.

Furthermore, the gate electrode is formed over the semiconductor substrate with a gate insulating film there between. An insulating layer is formed on the sides of the gate electrode. The semiconductor substrate on both side of the insulating layer is partially recessed. A material for suppressing semiconductor growth on the insulating layer is supplied onto the insulating layer and the recessed semiconductor substrate the surfaces of which are exposed. In addition, a material for a semiconductor layer is supplied onto the insulating layer and the recessed semiconductor substrate. The semiconductor layer is made to epitaxial-grow on the recessed semiconductor substrate, and the source/drain electrodes are formed.

As a result, selectivity under which the semiconductor layer is made to epitaxial-grow in a state in which the insulating layer and the recessed semiconductor substrate are exposed is improved, and the growth of the semiconductor layer on the insulating layer formed on the sides of the gate electrode can be suppressed. Therefore, an OFF-state leakage current which flows between the source/drain electrode and the gate electrode can be suppressed and the productivity of semiconductor devices can be enhanced.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. An epitaxial growth method for making a semiconductor selectively epitaxial-grow, the method comprising the steps of:
supplying a material for suppressing semiconductor growth on an insulating layer onto a surface on which the insulating layer and a first semiconductor layer are exposed; and
supplying a material for forming a second semiconductor layer onto the surface onto which the material for suppressing the semiconductor growth is supplied.

2. The epitaxial growth method according to claim 1, wherein the material for suppressing the semiconductor growth is gas which contains a halogen element.

3. The epitaxial growth method according to claim 1, wherein in the step of supplying the material for suppressing the semiconductor growth:
gas which contains a halogen element is used as the material for suppressing the semiconductor growth;
the gas which contains the halogen element is supplied together with carrier gas; and
when the gas which contains the halogen element is supplied, pressure in an atmosphere is between 10 and 10,000 Pa.

4. The epitaxial growth method according to claim 1, wherein when the material for suppressing the semiconductor growth is supplied, substrate temperature is between 450 and 600° C.

5. The epitaxial growth method according to claim 1, wherein when the second semiconductor layer is made to epitaxial-grow on the first semiconductor layer, substrate temperature is between 450 and 600° C.

6. The epitaxial growth method according to claim 3, wherein partial pressure of the gas which contains the halogen element is between 1 and 700 Pa.

7. The epitaxial growth method according to claim 3, wherein partial pressure of the carrier gas is higher than or equal to 1 Pa and is lower than 10,000 Pa.

8. A semiconductor device fabrication method comprising the steps of:
forming a gate electrode over a semiconductor substrate with a gate insulating film there between;
forming an insulating layer on sides of the gate electrode;
partially recessing the semiconductor substrate on both sides of the insulating layer;
supplying a material for suppressing semiconductor growth on the insulating layer onto a surface on which the insulating layer and the semiconductor substrate recessed are exposed; and
forming source/drain electrodes by supplying a material for a semiconductor layer onto the surface onto which the material for suppressing the semiconductor growth is supplied and by making the semiconductor layer epitaxial-grow on the semiconductor substrate recessed.

9. The semiconductor device fabrication method according to claim 8, wherein the semiconductor substrate or the semiconductor layer is formed of silicon, silicon which contains germanium, or germanium.

10. The semiconductor device fabrication method according to claim 8, wherein the material for suppressing the semiconductor growth is gas which contains a halogen element.

11. The semiconductor device fabrication method according to claim 8, wherein in the step of supplying the material for suppressing the semiconductor growth:
gas which contains a halogen element is used as the material for suppressing the semiconductor growth;
the gas which contains the halogen element is supplied together with carrier gas; and
when the gas which contains the halogen element is supplied, pressure in an atmosphere is between 10 and 10,000 Pa.

12. The semiconductor device fabrication method according to claim 8, wherein when the material for suppressing the semiconductor growth is supplied, substrate temperature is between 450 and 600° C.

13. The semiconductor device fabrication method according to claim 8, wherein when the semiconductor layer is made to epitaxial-grow on the semiconductor substrate, substrate temperature is between 450 and 600° C.

14. The semiconductor device fabrication method according to claim 11, wherein partial pressure of the gas which contains the halogen element is between 1 and 700 Pa.

15. The semiconductor device fabrication method according to claim 11, wherein partial pressure of the carrier gas is higher than or equal to 1 Pa and is lower than 10,000 Pa.
